(19) United States
(12) Patent Application Publication
(10) Pub. No.: US 2008/0079477 A1
(43) Pub. Date: Apr. 3, 2008

(54) Attenuators with progressive biased field-effect transistors

(76) Inventor: Michael Wendell Vice, El Granada, CA (US)

Correspondence Address: Kathy Manke;Avago Technologies Limited, 4380 Ziegler Road, Fort Collins, CO, 80525, US

(21) Appl. No.: 11/541,476

(22) Filed: Sep. 29, 2006

(51) Int. Cl. H03K 17/687

(52) U.S. Cl. 327/430

(57) ABSTRACT

An electrical circuit having improved linearity includes a resistive circuit having a plurality of field effect transistors (FETs) and one or more gate biasing circuits.

### CROSS-REFERENCE TO RELATED APPLICATION

The present application is related to the following U.S. patent applications: GATE LOAD IMPEDANCE NETWORKS FOR FIELD EFFECT TRANSISTOR ATTENUATORS AND MIXERS to Michael Vice, and having Ser. No. (AVAGO Docket Number: 10060147).

### BACKGROUND

Designers of RF and microwave systems often rely on resistive field effect transistor (FET) circuits to control the behavior of various signals of interest. For example, designers use both series and shunt FET-based devices in attenuators to variably attenuate high-frequency signals, as well as in mixers to multiply two or more high-frequency signals.

Unfortunately, shunt-configured FETs can create considerable signal distortion due to their inherent non-linearity. Often, the distortion in a shunt-configured FET is worst when the gate bias voltage applied to the FET is approximately half-way between the pinch-off voltage of the FET and the hard-on voltage of the FET. As is known, the pinch-off voltage is the gate voltage that substantially depletes the channel of carriers, causing the FET to behave like an open circuit; and hard-on is the gate voltage that enhances carrier concentration to a substantially maximum level, creating a condition of low resistance in the FET. While this distortion can be reduced by judiciously setting the channel bias, even with the optimal channel bias the distortion can still be excessive.

In order to address distortion problems, designers have often opted to increase the area (size) of the FET. Unfortunately, larger FET size lead to higher device capacitance, which in turn can preclude usage with high-frequency devices over large frequency bandwidths. Further, the use of rather large FETs can be expensive and can interfere with the efficient layout of a circuit on a semiconductor substrate.

Therefore, there is a need to improve the linearity of FET-based circuitry.

### SUMMARY

In an illustrative embodiment, an electrical circuit includes a variably resistive circuit having a plurality of field effect transistors (FETs) with each FET including a gate with a conductive channel controlled by the gate, a first channel terminal connected to one end of the conductive channel and a second channel terminal connected to the other end of the conductive channel, and one or more gate offset biasing circuits with each gate offset biasing circuit coupled to the gate of a respective FET and adapted to provide a bias offset voltage to its respective gate such that a pattern of differing bias offset voltages is provided to the plurality of gates.

In another illustrative embodiment, an electrical circuit includes a variably resistive circuit having a plurality of field effect transistors (FETs) with each FET including a gate with a conductive channel controlled by the gate, a first channel terminal connected to one end of the conductive channel and a second channel terminal connected to the other end of the conductive channel, and a biasing means coupled to each FET gate for providing a distribution of differing gate bias offset voltages adapted to improve the resistive linearity of the resistive circuit.

In yet another illustrative embodiment, a method for operating a variably resistive circuit to improve the linearity of the resistive circuit, wherein the resistive circuit includes a plurality of field effect transistors (FETs) with each FET including a gate with a conductive channel controlled by the gate, a first channel terminal connected to one end of the conductive channel and a second channel terminal connected to the other end of the conductive channel is disclosed. The method includes providing a pattern of differing gate bias offset voltages to the gate of each FET to improve the linearity of the resistive circuit.

### DESCRIPTION OF THE DRAWINGS

The example embodiments are best understood from the following detailed description when read with the accompanying drawing figures. Wherever applicable and practical, like reference numerals refer to like elements.

FIG. 1 is a known attenuation circuit.

FIG. 2 is a resistive attenuation circuit arranged in a shunt configuration in accordance with a representative embodiment.

FIG. 3 is an illustrative embodiment of a resistive attenuation circuit used to generate the performance curves of FIG. 4.

FIG. 4 depicts various performance curves of the improved resistive attenuation circuit of FIG. 3.

FIG. 5 is a resistive attenuation circuit arranged in a series configuration in accordance with another representative embodiment.

FIG. 6 is a resistive attenuation circuit arranged in a shunt configuration in accordance with yet another representative embodiment.

FIG. 7 is a resistive attenuation circuit arranged in a series configuration in accordance with still another representative embodiment.

FIG. 8 is a flowchart outlining a process for improving the operational linearity of a FET-based attenuation circuit in accordance with the disclosed methods and systems.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatus and methods may be omitted so as to not obscure the description of the example embodiments. Such methods and apparatus are clearly within the scope of the present teachings.

For the following disclosure, it should be appreciated that the terms “source” and “drain” as pertaining to a field effect transistor (FET) can be used interchangeably. That is, as the sources and drains for many FETs have no discernable differences, the terms should be considered interchangeable unless otherwise stated. Accordingly, while the usage of these terms in the following descriptions is made consistent with traditional usage for ease of explanation, sources and drains should be considered interchangeable or thought of as a first end and second end of a FET channel.

The embodiments described herein include FETs that may be implemented in a variety of materials. Representative materials include III-V semiconductors such as GaAs, InGaAs, and InGaAsP of selected stoichiometry. Such devices are commonly Metal Semiconductor FETs or MESFETs. However, the embodiments may be realized in other materials such as Si or SiGe. It is emphasized that the noted materials are illustrative and that other materials are contemplated.

As discussed above, known approaches to improving the linearity of FET-based resistive attenuators that rely on the usage of very large FETs can have adverse effects on frequency response, increase overall circuit size and impede efficient circuit layout on a semiconductor substrate. The disclosed methods and systems can resolve all of these issues.

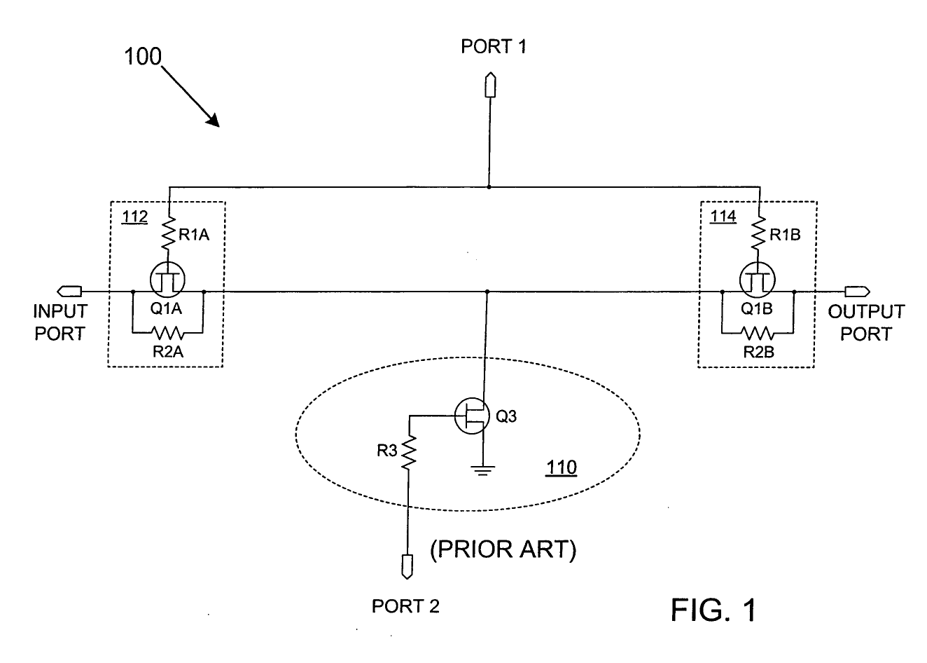

FIG. 1 is a schematic of a known FET-based attenuation circuit 100. As shown in FIG. 1, the known FET-based attenuation circuit 100 includes a first series resistive device 112 coupled to a second series resistive device 114 with a shunt-configured resistive device 110 disposed between the two series resistive devices 112 and 114. The first series resistive device 112 includes FET Q1A and resistors R1A and R2A. The second series resistive device 114 includes FET Q1B and resistors R1B and R2B. The shunt-configured resistive device 110 includes a FET Q3 and resistor R3.

In operation, the FET-based attenuation circuit 100 can be biased by applying an appropriate biasing voltage at PORT 1 shown at the top of FIG. 1. Additionally, the attenuation level of the attenuation circuit 100 can be set by applying an appropriate gate bias voltage at PORT 2, which leads to the gate of FET Q3 via resistor R3.

After the FET-based attenuation circuit 100 is biased and its attenuation level set, a signal can be provided to the INPUT PORT (at the left-hand side of FIG. 1) where it can propagate through the series resistive devices 112 and 114 to the OUTPUT PORT. As the signal propagates from the INPUT PORT to the OUTPUT PORT, some of its energy will be siphoned through the shunt-configured resistive device 110 to signal/electrical ground as a function of the channel resistance of FET Q3.

However, as discussed above, FETs can create considerable signal distortion due to their inherent non-linearity, which tends to be predominant at intermediate levels of attenuation. Accordingly, it should be appreciated that the shunt-configured resistive device 110 of FIG. 1 can introduce an unacceptable amount of distortion into a signal as it passes from the INPUT PORT to the OUTPUT PORT.

In order to compensate for distortion introduced by a given FET, the developer of the disclosed methods and systems has devised a novel approach by using a bank of multiple FETs with each FET having a different gate bias offset voltage. While each individual FET may still introduce its own distortion, a benefit of using multiple FETs is that, by applying the proper distribution of gate offset biasing, the FETs can mutually compensate for one other in a way that will reduce overall distortion.

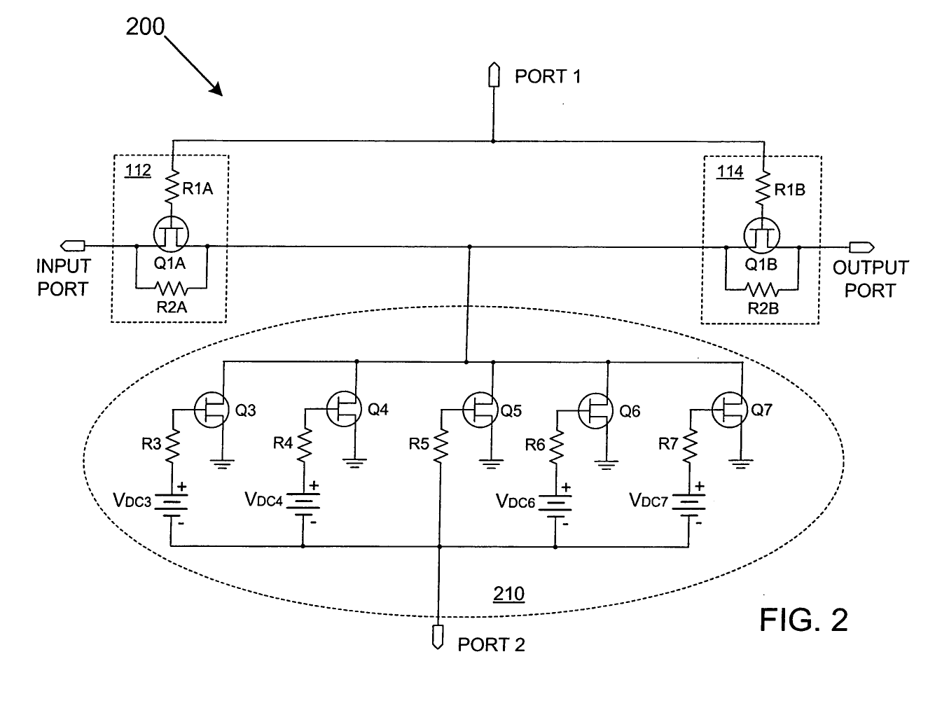

FIG. 2 is a schematic diagram of an FET-based attenuation circuit 200 in accordance with a representative embodiment of the disclosed methods and systems. As shown in FIG. 2, the FET-based attenuation circuit 200 is similar to the known FET-based attenuation circuit 100 of FIG. 1. However, the FET-based attenuation circuit 200 uses a shunt-configured resistive device 210 having multiple FETs Q3-Q7 arranged in parallel with respect to one another.

As shown in FIG. 2, each of the FETs Q3-Q7 is commonly coupled to PORT 2 via a respective gate resistor R3-R7. Accordingly, by varying the voltage of PORT 2, an external device can manipulate the collective resistance of the plurality of FETs Q3-Q7. While all of the FETs Q3-Q7 can be commonly controlled using PORT 2, four of the five FETs Q3, Q4, Q6 and Q7 have respective voltage offset devices V_{DC3}, V_{DC4}, V_{DC6} and V_{DC7}. The end result is that each of the FETs Q3-Q7 can have a different gate voltage V_{GS} at any given time. By judiciously selecting the distribution of FET gate bias offset voltages, the distortion introduced by the individual FETs Q3-Q7 can be made to be mutually compensating so that overall distortion is reduced.

While the voltage offset devices V_{DC3}, V_{DC4}, V_{DC6} and V_{DC7} are depicted as batteries, in various embodiments the voltage offset devices V_{DC3}, V_{DC4}, V_{DC6} and V_{DC7} can take any number of forms, such as a collection of electronic circuits or electrochemical devices, as may be found practical or advantageous.

Also note that, while the number of possible distribution patterns of gate bias offset voltages for a bank of FETs is literally infinite, the developer of the disclosed methods and systems has devised an approach for defining a gate bias offset voltage distribution that is highly effective. Generally, the gate bias offset voltage of each FET gate can be constrained to be a constant from FET gate to FET gate. For example, for a bank of M number of FETs, each FET gate voltage V_{GS,N} can be defined to be:

V_{GS,N}≈N×V_{EPSILON}+V_{OFFSET}, EQ. 1

where V_{EPSILON} and V_{OFFSET} are constants and N is an integer ranging from [1:M]. By way of example, by setting M=4, V_{EPSILON}=0.25 volts and V_{OFFSET}=−0.25 volts, the distribution of offset voltages can be defined as V_{GS,1}=0.0 volts, V_{GS,2}=0.25 volts, V_{GS,3}=0.5 volts and V_{GS,4}=0.75 volts.

Note that by varying the gate voltage difference V_{EPSILON} throughout a practical voltage range (e.g., 0 volts to 0.5 volts), a designer will be able to identify an optimal gate voltage difference V_{EPSILON} that provides the best performance for a given plurality of FETs.

In addition to varying the FET gate bias voltages, in various embodiments it can be useful to vary the size of the various FETs Q3-Q7 as well. In this disclosure, the term “size” is meant to refer to the total gate periphery. For example, if a FET has four gate fingers and each finger has a gate width of 50 um, then the FET is said to have a size of 200 um.

While, as with gate bias distributions, the number of possible distribution patterns of FET sizes is virtually infinite, the developer of the disclosed methods and systems has devised an approach to determining FET size wherein the size A_{SIZE,N} of each FET varies according to the following equation:

A_{SIZE,N}≈N×A_{DELTA}+A_{OFFSET}, EQ. 2

where A_{DELTA} and A_{OFFSET} are constants, N is an integer ranging from [1:M] and M is the number of FETs.

For example, using this approach and defining A_{DELTA}=10 um² and A_{OFFSET}=5 um², the size of FETs Q3-Q7 respectively can be set to 15 um², 25 um², 35 um², 45 um² and 55 um².

Alternatively, the size Wn of the nth FET may be given generally as

nth FET size=Wn=Woⁿ, EQ. 3

While the distributions in FET size and gate bias offset voltages can be independently set, it should be appreciated that it can be beneficial to correlate FET size and gate voltage distribution. For example, in various embodiments, it can be beneficial to cause the smallest FET to be the first device to begin turning on, the second smallest FET to be the next device to turn on and so forth. In various embodiments where n-channel FETs are used, this means that the smallest FET should have the largest (most positive) V_{GS}. In contrast, in the case where p-channel FETs are used, then the smallest FET should have the lowest (most negative) value of V_{GS}.

Still further, in order to improve individual FET linearity over a range of attenuation settings, a capacitor (or equivalent device, such as an appropriately configured FET or Schottkey diode) can be added between the gate of each FET Q3-Q7 and a ground (or equivalent) node. Details of this approach to decreasing individual FET distortion can be found in the referenced patent application entitled “GATE LOAD IMPEDANCE NETWORKS FOR FIELD EFFECT TRANSISTOR ATTENUATORS AND MIXERS”.

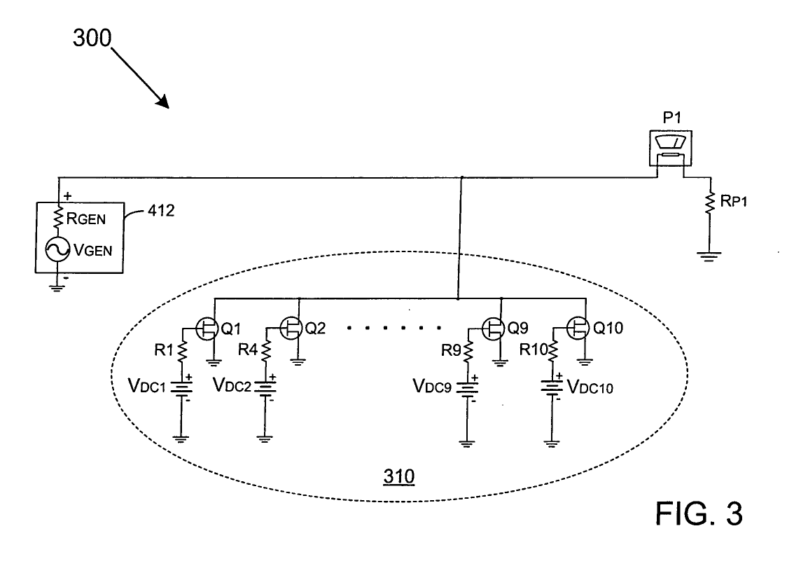

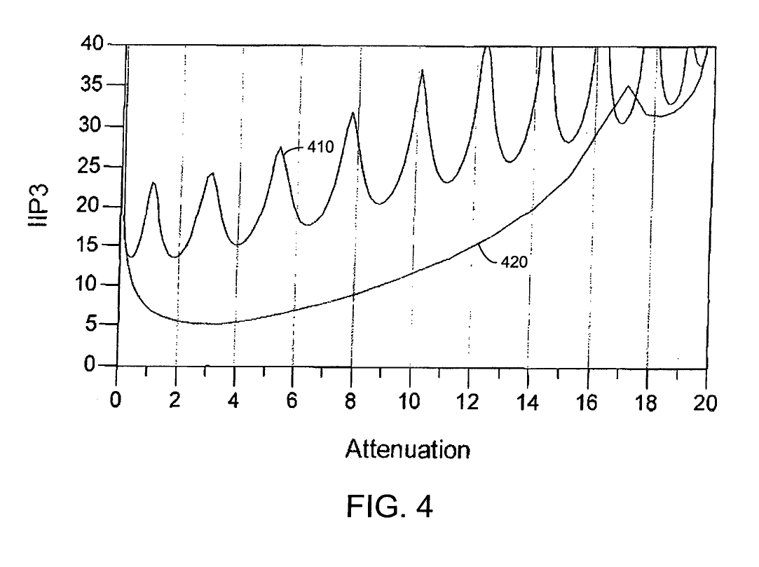

FIG. 3 depicts a specific embodiment of a resistive attenuation circuit 300 used to generate a set of performance curves depicted in FIG. 4. As shown in FIG. 3, the resistive attenuation circuit 300 has a similar configuration to the resistive attenuation circuit 200 of FIG. 2 with the exception that the shunt-configured resistive device 110 has ten (10) FETs Q1-Q10 with respective gate resistors R1-R10 and gate biasing devices V_{DC1} to V_{DC10}. While not shown in FIG. 3, the size of the individual FETS Q1-Q10 ranges in multiples of 9.091 um for a total size of 500 um with FET Q1 being the smallest device at 9.091 um and FET Q10 being the largest device at 90.91 um. Each FET Q1-Q10 can be operated using a V_{GS} that is progressively smaller by a constant voltage than the previous FET such that the smallest FET Q1 is operated at the highest gate control voltage and the largest FET Q10 is operated at the lowest gate control voltage.

Continuing to FIG. 4, two performance curves 410 and 420 generated by the shunt-configured resistive device 110 of FIG. 3 are shown. The smooth (lower) performance curve/trace 420 represents the case where all of the FETs Q1-Q10 of FIG. 3 are operated with identical V_{GS} values, i.e., V_{EPSILON}=0.0 volts. The lumpy (upper) curve/trace 410 represents the case where the FETs Q1-Q10 of FIG. 3 have progressively lower gate control voltage values defined by V_{EPSILON}=0.3 volts.

Note that the performance of trace 420 dips to a minimum value at an intermediate attenuation range while the linearity at the maximum and minimum attenuation states is considerably better than it is at the dip. In view of trace 420, it stands to reason that if a multitude of FETs are all operated in parallel and at the same V_{GS} at which device linearity is minimal, the resultant linearity of the collective FETs of the shunt device 310 will be at the worst possible attainable value.

However, if on the other hand the FETs Q1-Q10 are operated at different gate control voltages, the regions of good performance for each FET Q1-Q10 can be made to compensate for the poor performance regions. The result is that the worst-case attenuator linearity at intermediate attenuation ranges is substantially improved while the linearity at the low and high attenuation ranges remains unchanged.

During the design process, a designer can determine the optimal V_{EPSILON} value by sweeping V_{EPSILON} from 0.0 volts to some maximum practical value. As V_{EPSILON} increases, the lower curve 420 will both rise and its shape will morph to develop the characteristic peaks and valleys seen in curve 410, which was produced using a V_{EPSILON} of 0.3 volts. While curve 410 shows a substantial performance increase over curve 420, experience has shown that beyond a certain point, a further increase in V_{EPSILON} will produce negative performance returns.

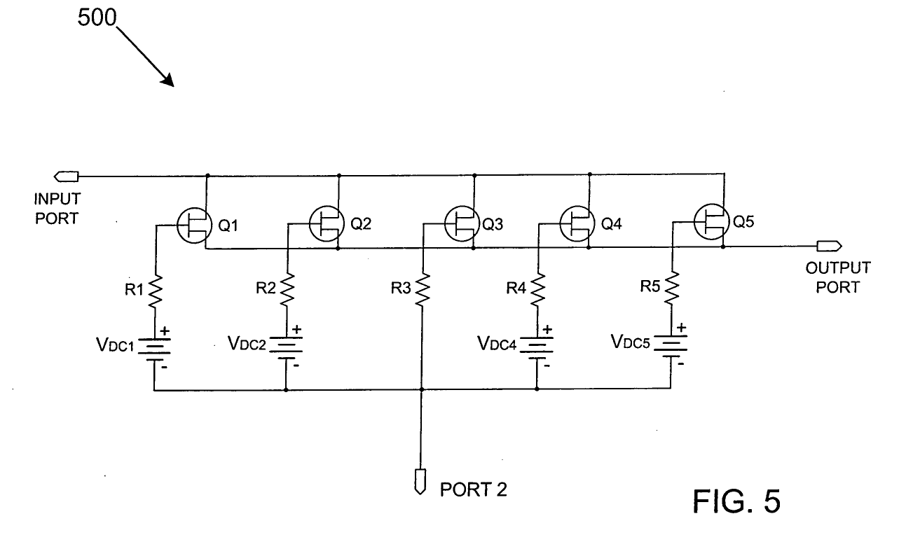

FIG. 5 is a resistive attenuation circuit 510 arranged in a series configuration in accordance with another representative embodiment. Note that, as with FIGS. 2 and 3, the FETs Q1-Q5 of FIG. 5 are arranged in parallel with respect to one another. However, unlike the shunt configuration examples of FIGS. 2 and 3, the present resistive attenuation circuit 510 as a whole is configured to work as a series resistive device such that the INPUT PORT and OUTPUT PORT are both signal-carrying nodes.

As will be appreciated, multiple FETs in series (i.e., source to drain connected in a daisy chain fashion), may be effected as a multigate FET, having source and drain channel ends with multiplicity of consecutive gates between them.

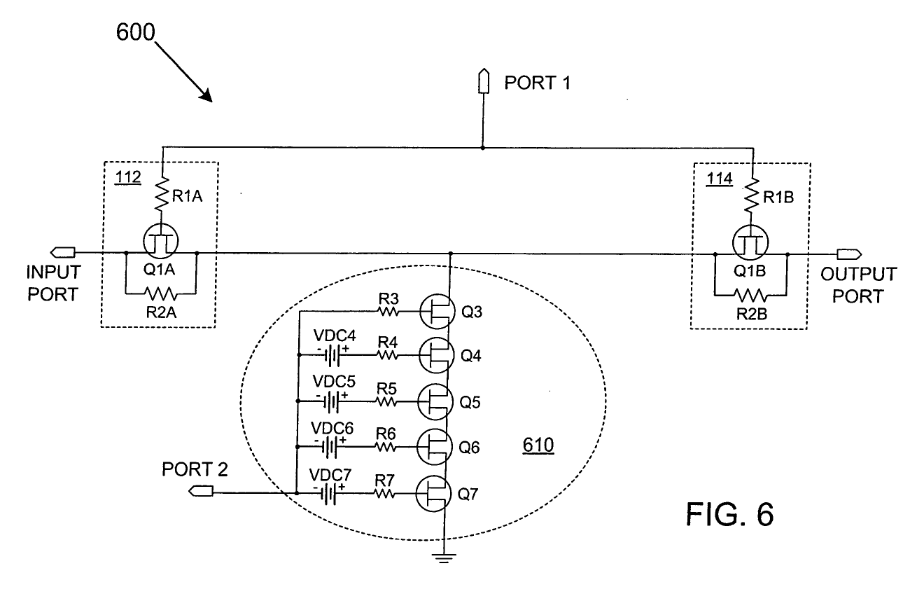

FIG. 6 is a resistive attenuation circuit 600 arranged in a shunt configuration in accordance with yet another representative embodiment. As shown in FIG. 6, the overall circuit configuration is similar to that of FIG. 2. However, a review of FIG. 6 shows that the shunt attenuation circuit 610 varies substantially from the shunt attenuation circuit 210 of FIG. 2. That is, instead of being arranged in parallel with respect to one another, the FETs Q3-Q7 of FIG. 6 are sequentially chained together via their first and second channel terminals. The resultant chain of FETs has two ends including a first (upper) end (of FET Q3) coupled to a signal-carrying node and a second (bottom) end (of FET Q7) coupled to ground.

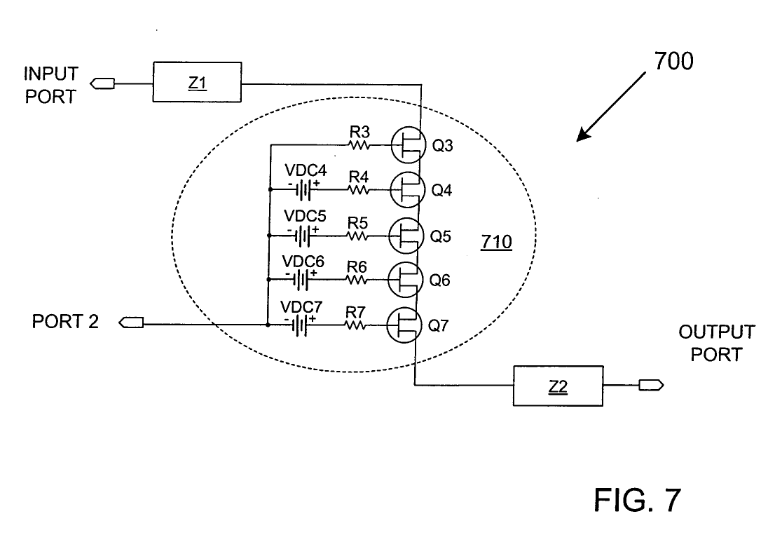

FIG. 7 is a resistive attenuation circuit 710 arranged in a series configuration in accordance with still another representative embodiment. Devices Z1 and Z2 can be any number impedance networks, including resistive shunt devices. Note that, like the embodiment of FIG. 6, the individual FETs Q3-Q7 are sequentially chained together via their first and second channel terminals. However, unlike the attenuation circuit 610 circuit of FIG. 6, the present attenuation circuit 710 is not arranged as a shunt device. That is, as can be seen in FIG. 7 the present resistive attenuation circuit 710 as a whole is arranged as a series resistive device such that both ends of the attenuation circuit 710 are signal-carrying nodes.

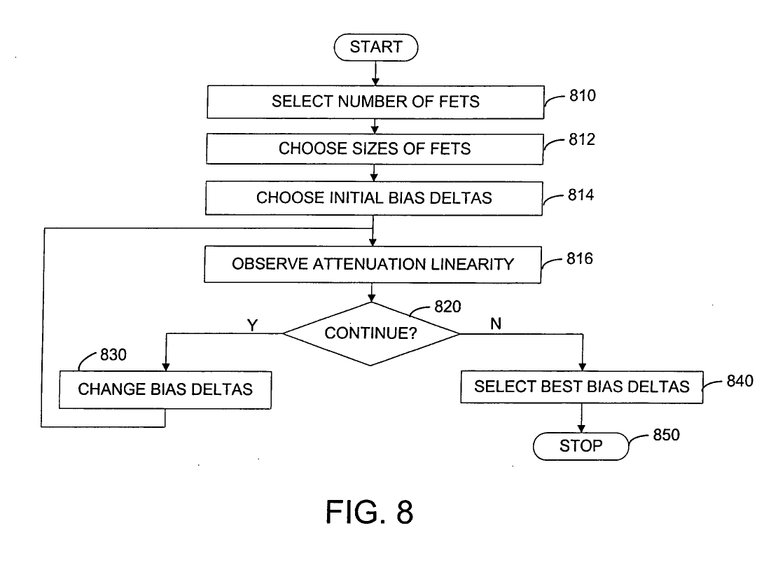

FIG. 8 is a flowchart outlining a process for improving the operational linearity of a FET-based circuit that uses a plurality of FETs, such as any of the FET-based attenuators of FIGS. 2-3 and 5-7. The process starts in step 810 where a number of FETs for a FET-based variably resistive device is determined. Next, in step 812, the size of the individual FETs is chosen. While for the present example the size of each FET can vary according to EQ. 2 above, as also mentioned above it is possible that the distribution of FET sizes can take an infinite number of variations from embodiment to embodiment. Control continues to step 814.

In step 814, an initial FET gate voltage difference (V_{EPSILON}) is selected. While the present process uses a distribution of FET gate offset voltages defined by EQ. 1 above, as mentioned above the particular distribution of gate voltage can take an infinite number of variations from embodiment to embodiment. Control continues to step 816.

In step 816, the attenuation linearity of the FET-based circuit is observed. Next, in step 820, a determination is made as to whether to continue to test for further gate voltage difference values. If the FET circuit is to be tested for more gate voltage difference values, control jumps to step 830; otherwise, control jumps to step 840.

In step 830, a new V_{EPSILON} value is selected, and control jumps back to step 816 where the attenuation linearity of the FET-based circuit is observed using the new V_{EPSILON} value. Note that there is no requirement that V_{EPSILON} must vary in any set way. However, in various embodiments it can be useful to vary V_{EPSILON} in constant small increasing or decreasing increments across some useful and practical range of voltages.

In step 840, which assumes that the attenuation linearity of the FET-based circuit has been tested for a sufficient number of V_{EPSILON} values, the best V_{EPSILON} value based on the observations of step 816 can be selected, and control can continue to step 850 where the process stops.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. An electrical circuit, comprising:
a variably resistive circuit having a plurality of field effect transistors (FETs), wherein each FET includes:
a gate with a conductive channel controlled by the gate;
a first channel terminal connected to one end of the conductive channel; and
a second channel terminal connected to the other end of the conductive channel; and
one or more gate offset biasing circuits with each gate offset biasing circuit coupled to the gate of a respective FET and adapted to provide a bias offset voltage to its respective gate such that a pattern of differing bias offset voltages is provided to the plurality of gates.

2. The electrical circuit of claim 1, further comprising a common gate biasing node coupled to the gates of the plurality of FETs for conveying a variable control voltage for common control of the plurality of FETs.

3. The electrical circuit of claim 1, wherein the pattern of differing bias offset voltages has a voltage distribution configured to substantially improve the resistive linearity of the resistive circuit.

4. The electrical circuit of claim 3, wherein the plurality of FETs are arranged in parallel with respect to one another such that each first channel terminal is electrically coupled to a first signal-carrying node and each second channel terminal is electrically coupled to a second node.

5. The electrical circuit of claim 4, wherein the resistive circuit is configured in a shunt configuration with the second node being a ground node.

6. The electrical circuit of claim 4, wherein each FET further includes a respective capacitive device coupled between its gate and a ground node with the respective capacitive devices adapted to improve the resistive linearity of each individual FET.

7. The electrical circuit of claim 6, wherein the capacitive devices are at least one of FETs or diodes.

8. The electrical circuit of claim 4, wherein the resistive circuit is arranged as a series element with respect to a signal path such that the second node is a signal carrying node.

9. The electrical circuit of claim 3, wherein the plurality of FETs are sequentially chained together via their first and second channel terminals.

10. The electrical circuit of claim 9, wherein the resistive circuit is arranged in a shunt configuration with the second node being a ground node.

11. The electrical circuit of claim 9, wherein the resistive circuit is arranged as a series element with respect to signal path such that the second node is a signal carrying node.

12. The electrical circuit of claim 1, wherein the electrical circuit includes at least three FETs with at least two FETs having gate biasing circuits.

13. The electrical circuit of claim 3, wherein the gate bias offset voltage V_{BIAS, N} provided to the respective FET gates is approximately V_{BIAS, N}=N×V_{EPSILON}+V_{OFFSET}, where V_{EPSILON} and V_{OFFSET} are constants, N is an integer ranging from [1:M] and M is the number of FETs.

14. The electrical circuit of claim 3, wherein each FET of the plurality of FETs varies in size with respect to one another, and wherein and the gate bias offset voltage of each FET's gate decreases with increasing FET size.

15. The electrical circuit of claim 1, wherein the size A_{SIZE,N} of each FET of the plurality of FETs varies according to the equation A_{SIZE,N}=N×A_{DELTA}+A_{OFFSET}, where A_{DELTA} and A_{OFFSET} are constants, N is an integer ranging from [1:M] and M is the number of FETs.

16. An electrical circuit, comprising:
a variably resistive circuit having a plurality of field effect transistors (FETs) with each FET including:
a gate with a conductive channel controlled by the gate;
a first channel terminal connected to one end of the conductive channel; and
a second channel terminal connected to the other end of the conductive channel; and
a biasing means coupled to each FET gate for providing a distribution of differing gate bias offset voltages adapted to improve the resistive linearity of the resistive circuit.

17. The electrical circuit of claim 16, wherein each FET has a different size with respect to the other FETs.

18. The electrical circuit of claim 17, wherein the gate voltage of each FET varies as a function of FET size such that the smallest FET is the first FET to turn on when the resistive circuit transitions from a high impedance to a low impedance.

19. A method for operating a variably resistive circuit to improve the linearity of the resistive circuit, wherein the resistive circuit includes a plurality of field effect transistors (FETs) with each FET including a gate with a conductive channel controlled by the gate, a first channel terminal connected to one end of the conductive channel and a second channel terminal connected to the other end of the conductive channel, the method comprising:
providing a pattern of differing gate bias offset voltages to the respective gates of the FETs to improve the linearity of the resistive circuit.

20. The method of claim 19, wherein each FET has a different size, and the gate bias offset voltage of each FET varies as a function of FET size such that the smallest FET is the first FET to turn on when the resistive circuit switches from an open circuit to a low impedance.
